(19) United States
(12) Patent Application Publication
(10) Pub. No.: US 2012/0146113 A1
(43) Pub. Date: Jun. 14, 2012

(54) SEMICONDUCTOR DEVICE AND METHOD FOR FABRICATING THE SAME

(75) Inventors: JUN SUZUKI, Toyama (JP); TAKAAKI SAKURAI, Toyama (JP)

(73) Assignee: PANASONIC CORPORATION, Osaka (JP)

(21) Appl. No.: 13/397,890

(22) Filed: Feb. 16, 2012

Related U.S. Application Data
(63) Continuation of application No. PCT/JP2010/001183, filed on Feb. 23, 2010.

(30) Foreign Application Priority Data
Sep. 4, 2009 (JP) 2009-204581

(51) Int. Cl. H01L 29/78; H01L 21/285

(52) U.S. Cl. 257/288; 438/591; 438/585; 257/E21.19; 257/E29.255

(57) ABSTRACT

A method for fabricating a semiconductor device, the method comprising: forming a metal containing film on a substrate; exposing the metal containing film to an ammonia radical in a reaction chamber; evacuating gas generated in the exposing by supplying an inert gas into the reaction chamber; and after repeating the exposing and the supplying a predetermined number of times, forming a silicon nitride film covering the metal containing film in the reaction chamber without atmospheric exposure.

### CROSS-REFERENCE TO RELATED APPLICATIONS

This is a continuation of PCT International Application PCT/JP2010/001183 filed on Feb. 23, 2010, which claims priority to Japanese Patent Application No. 2009-204581 filed on Sep. 4, 2009. The disclosures of these applications including the specifications, the drawings, and the claims are hereby incorporated by reference in their entirety.

### BACKGROUND

With increased speed and increased integration density of semiconductor devices, the size of transistors is decreasing.

Among semiconductor devices, complementary metal oxide semiconductor (complementary MOS, CMOS) devices include two types of transistors, an n-channel MOS (NMOS) transistor and a p-channel MOS (PMOS) transistor. The NMOS transistor controls on and off of currents by transfer of electrons, and the PMOS transistor controls on and off of currents by transfer of holes.

Conventionally, a gate insulating film used in a CMOS device is made of a silicon dioxide film, in general, and has a dielectric constant of about 3.9. However, when a gate insulating film has a reduced thickness since the size of transistors has been reduced, a leakage current is increased, and the power consumption and standby power consumption of the device are increased. Thus, the development of a high-k (high dielectric) gate insulating film has been conducted to allow reduction in equivalent oxide thickness (EOT) of the high-k gate insulating film even when an actual thickness of the high-k gate insulating film is larger than that of a silicon oxide film, using a gate insulating film having a dielectric constant of 4.0 or more.

However, if a conventional polysilicon gate electrode and a conventional high-k gate electrode are simply combined, a phenomenon called “depletion” of a gate electrode occurs. This is a phenomenon in which a depletion layer capacitance is generated between the high-k gate insulating film and the polysilicon gate electrode, thus eliminating the advantage that the EOT of the high dielectric gate insulating film is small. To reduce or prevent depletion of the gate electrode, it is necessary to combine a metal gate electrode, instead of the polysilicon gate electrode, with the high-k gate electrode. Furthermore, in forming a CMOS device, it is important to control a threshold voltage (Vt) at a proper level using the high-k gate insulating film/metal gate electrode.

When a conventional combination of a silicon oxide gate insulating film/a polysilicon gate electrode is used, an impurity such as boron or phosphorous is ion-implanted into polysilicon, and thermal treatment is performed to activate the impurity, thus improving the work function of polysilicon. For example, when polysilicon is not doped with an impurity, the work function of polysilicon is 4.65 eV, but the work function can be increased up to 5.15 eV by ion-implanting boron into polysilicon. By using this technique, threshold voltages Vt of a NMOS and a PMOS can be controlled.

However, when a high-k gate insulating film is used, due to traps contained in high density in the high-k gate insulating film, the Fermi level pinning which is a phenomenon in which the Fermi level is fixed occurs. Therefore, the work function cannot be changed at a doping level achieved by ion implantation, and threshold voltages cannot be controlled. Furthermore, in a metal-inserted-poly-Si stack (MIPS) structure including a combination of a metal gate electrode and a polysilicon gate electrode, it is difficult to adjust the work function by ion implantation, and the work function of a metal used for a gate electrode is dominant in Vt control.

In studies of the work function in such a combination of a high-k gate insulating film and a metal gate electrode, a nitride of titanium, tungsten, tantalum, or molybdenum is used. As a metal gate electrode material, specifically, a nitride of titanium and a nitride of tungsten, each of which is nitride conventionally used as a metal gate material of a DRAM, are easy to handle in view of processing characteristics of dry etching, wet etching, or the like.

Moreover, after a MIPS gate structure is formed, offset spacers are formed on gate electrode sidewalls in order to form an extension ion injection layer. In the case of a high-k metal gate structure, when offset spacers are formed by using a silicon oxide film in a manner similar to that of a conventional technique, a metal gate electrode is oxidized by an oxidant serving as a source gas. For this reason, a silicon nitride film is used in many cases instead of the silicon oxide film.

N. Mise et al., Solid State Devices and Materials, 2007, pp. 724-725 (hereinafter referred to as Document 1) describes that the drivability of transistors can be improved by changing the film formation temperature of a silicon nitride film which will be processed into such offset spacers, and a source gas serving as a silicon source. Specifically, it is described that a silicon source containing no chlorine is used at a low temperature of about 400° C. to form the silicon nitride film.

Techniques in the background are also disclosed in Japanese Patent Publication No. 2004-186534, and the like.

### SUMMARY

However, when a gate metal film and a poly-Si film on the gate metal film are formed, and then are patterned by using a resist to perform gate etching, ashing caused by plasma oxidation to remove the resist and/or natural oxidation caused by being exposed to air oxidizes sidewalls of a metal gate electrode.

The oxidation of the sidewalls of the metal gate electrode may form a natural oxide film having a thickness of about 1 nm-2 nm, and/or an ashing oxide film having a thickness of about 2 nm-5 nm. When such oxidation of metal occurs, that is, when an insulating film is formed, the advantages of the metal gate electrode are damaged. In particular, when the gate length is shorter, the proportion of the oxide film to the gate length is larger even with the same thickness of the oxide film. Thus, the influence of the oxide film becomes large.

If for example, hydrofluoric acid-based cleaning is performed in order to remove such a metal oxide film, the high-k gate insulating film may be simultaneously etched. For this reason, cleaning at an excessive degree cannot be performed. Moreover, even if cleaning is performed, atmospheric exposure occurs before forming the silicon nitride film which will be the offset spacers. Thus, oxide films are necessarily formed on the sidewalls of the metal gate electrode.

In view of the foregoing, the technique of reducing an oxide layer of a metal gate electrode, and improving the drivability of a transistor in a high-k gate insulating film/metal gate electrode structure will be described below.

A method for fabricating a semiconductor device of the present disclosure includes: forming a metal containing film on a substrate; exposing the metal containing film to an ammonia radical in a reaction chamber; evacuating gas generated in the exposing by supplying an inert gas into the reaction chamber; and after repeating the exposing and the evacuating a predetermined number of times, forming a silicon nitride film covering the metal containing film in the reaction chamber without atmospheric exposure.

Note that the exposing and the evacuating may be repeated until a natural oxide film formed on a surface of the metal containing film is reduced.

With this method for fabricating a semiconductor device, in the exposing and the evacuating, the natural oxide film formed on the surface of the metal containing film can be reduced and nitrided with the ammonia radical. That is, reaction of oxygen in the natural oxide film formed on the surface of the metal containing film with hydrogen in the ammonia radical is caused to eliminate the oxygen and the hydrogen as water, and nitrogen in the ammonia radical is bonded to metal remaining after the elimination of the oxygen. The exposing and the evacuating (purging) the gas (eliminated as water, etc.) generated in the exposing by an inert gas are alternately performed, and then the silicon nitride film covering the metal containing film is formed in the same reaction chamber without atmospheric exposure, so that it is possible to prevent natural reoxidation of the metal containing film. Thus, when the metal gate electrode is formed as a metal containing film, the drivability can be less susceptible to degradation due to the oxide film.

The exposing may be performed within a temperature range from 400° C. to 800° C. both inclusive.

The ammonia radical may be generated by supplying ammonia between a pair of electrode plates to which a high-frequency voltage is applied.

The ammonia radical may be generated by supplying ammonia to a metal catalyst and irradiating the metal catalyst with an ultraviolet ray. The metal catalyst may include a platinum group element, Ti, Zr, or Mn.

The ammonia radical can thus be generated.

The metal containing film may be a metal gate electrode formed on the substrate via a high-dielectric-constant gate insulating film, and the high-dielectric-constant gate insulating film may include at least one of an oxide of a Group 4 element, an oxide of a Group 4 element and Si, or an oxide of a Group 4 element and Al. Moreover, the Group 4 element may be at least one of Hf or Zr.

The metal containing film may be a metal gate electrode formed on the substrate via a high-dielectric-constant gate insulating film, and the metal gate electrode may be made of an alloy containing a metallic element as a main component, a nitride of an alloy containing a metallic element as a main component, or a nitride of an alloy containing a metallic element as a main component and containing Si. Moreover, the metallic element may be at least one of Ti, W, Ta, Ru, or Al.

The metal containing film may be a metal gate electrode formed on the substrate via a high-dielectric-constant gate insulating film, a p-channel transistor including the high-dielectric-constant gate insulating film and the metal gate electrode may be formed, and the high-dielectric-constant gate insulating film may contain at least one of AlO or TaO.

The metal containing film may be a metal gate electrode formed on the substrate via a high-dielectric-constant gate insulating film, an n-channel transistor including the high-dielectric-constant gate insulating film and the metal gate electrode may be formed, and the high-dielectric-constant gate insulating film may contain at least one of LaO or MgO.

As a more specific configuration of the semiconductor device, such a configuration described above may be possible.

The metal containing film may be a metal gate electrode formed on the substrate via a high-dielectric-constant gate insulating film, and in the forming the metal containing film, thermal treatment within a temperature range from 700° C. to 1100° C. both inclusive may be performed on the high-dielectric-constant gate insulating film before forming the metal gate electrode. In particular, the heat treatment may be performed at about 1000° C.

With this method, while preventing reduction of the high-dielectric-constant gate insulating film, the natural oxide film can be selectively reduced. When the high-dielectric-constant gate insulating film is reduced, a function as an insulating film is damaged, thereby causing, for example, an increase in leakage current. Thus, it is preferable to prevent reduction of the high-dielectric-constant gate insulating film.

The metal containing film may be a metal gate electrode formed on the substrate via a high-dielectric-constant gate insulating film, and the silicon nitride film may be formed by atomic layer deposition (ALD), and may be processed into offset spacers.

Next, a semiconductor device of the present disclosure includes: a transistor structure including a metal gate electrode formed on a substrate via a high-dielectric-constant gate insulating film; and offset spacers made of a silicon nitride film formed on sidewalls of the metal gate electrode, wherein a concentration of segregated oxygen between the metal gate electrode and each offset spacer is equal to or lower than 1×10²⁰ atoms/cm³.

With this semiconductor device, the concentration of oxygen between the metal gate electrode and each offset spacer is sufficiently low, so that it is possible to prevent drivability reduction caused by oxidation of the metal gate electrode.

According to the technique described above, a natural oxide film formed on sidewalls of a metal gate electrode is reduced and nitrided in a reaction chamber used to form offset spacers, so that it is possible to prevent drivability reduction caused by an oxide film of the metal gate electrode.

### BRIEF DESCRIPTION OF THE DRAWINGS

FIG. 1 is a cross-sectional view schematically illustrating a configuration of an example semiconductor device of an embodiment of the present disclosure.

FIG. 2 is a view illustrating the nonlinearity of the gate leakage current with respect to the gate length.

FIG. 3 is a view illustrating results of SIMS analysis performed on an oxide layer at an interface between a silicon nitride film and a TiN film.

FIG. 4A is a view illustrating an example of a TiN film formation sequence of the embodiment of the present disclosure. FIG. 4B is a view illustrating an example of an ammonia radical generation mechanism.

FIG. 5A is a view illustrating a mechanism in which an ammonia radical reacts with a titanium oxide film. FIG. 5B is a view illustrating a reaction mechanism in which a titanium oxide film is nitrided by plasma.

FIG. 6 is a view illustrating the selective reduction property of TiN with respect to HfSiON and TiN.

FIG. 7A is a view illustrating the relationship between the gate length and the gate leakage current of an example and a comparative example. FIG. 7B is a view illustrating the transistor drive current of the example and the comparative example.

FIGS. 8A-8F are cross-sectional views schematically illustrating a method for fabricating the example semiconductor device of the embodiment of the present disclosure.

### DETAILED DESCRIPTION

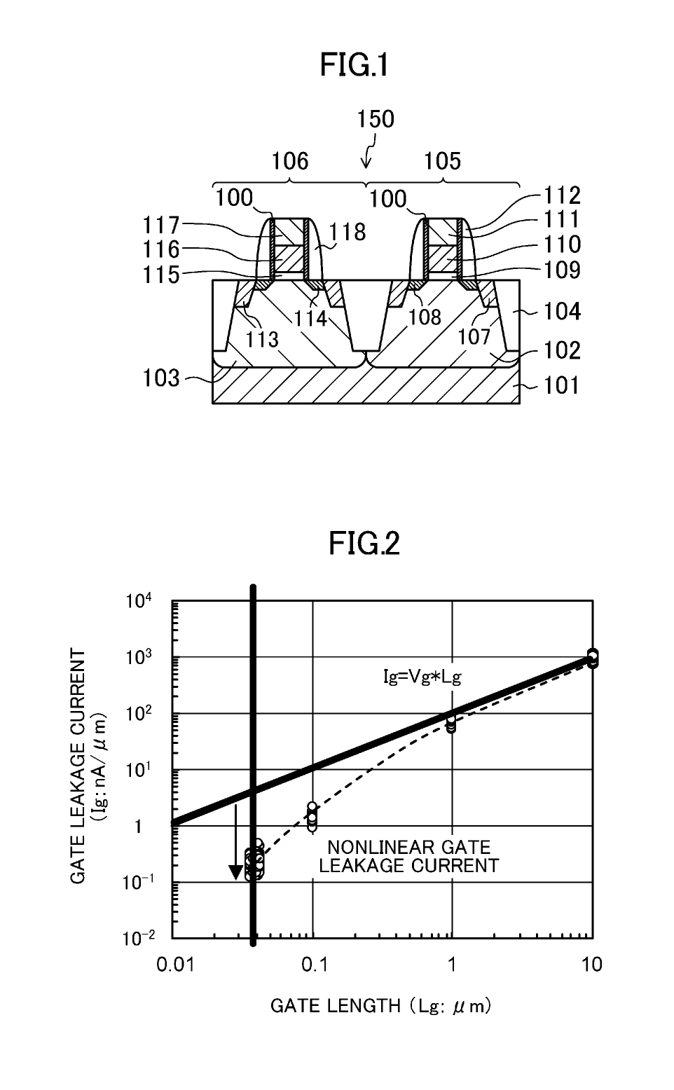

A semiconductor device of an embodiment of the present disclosure and a method for fabricating the same will be described below with reference to the drawings. FIG. 1 is a cross-sectional view schematically illustrating a CMOS structure included in an example semiconductor device 150 of a first embodiment of the present disclosure.

As illustrated in FIG. 1, a silicon substrate 101 is used to form the semiconductor device 150. A device isolation layer 104 made of a silicon oxide film as a shallow trench isolation (STI) partitions a surface portion of the silicon substrate 101 into sections, in which an n-type well region 102 and a p-type well region 103 formed by ion implantation are arranged, respectively.

A p-channel transistor 105 is formed in the n-type well region 102. The p-channel transistor 105 includes a gate insulating film 109 serving as a high-k (high dielectric constant) gate insulating film formed on the n-type well region 102, a PMOS metal gate electrode 110 formed on the gate insulating film 109, and a polysilicon electrode 111 which is formed on the metal gate electrode 110, and in which ions of an impurity such as boron are implanted. In the n-type well region 102, a p-type extension layer 108 formed by ion implantation and a p-type diffusion layer 107 formed outside the p-type extension layer 108 are positioned on both sides of the metal gate electrode 110. Offset spacers 100 made of a silicon nitride film are formed to cover sidewalls of the metal gate electrode 110 and the polysilicon electrode 111. Sidewalls 112 made of a silicon oxide film and a silicon nitride film are further formed on side surfaces of the offset spacers 100.

Moreover, upper portions of source/drain regions formed by the p-type diffusion layer 107 and the p-type extension layer 108, and an upper portion of the polysilicon electrode 111 are silicided with nickel silicide (NiSi) or nickel platinum silicide (NiPtSi) (not shown). Moreover, a SiGe epitaxial layer containing 10%-30% of germanium (Ge) (not shown) may be formed in the p-type source/drain region.

An n-channel transistor 106 is formed in the p-type well region 103. The n-channel transistor 106 includes a gate insulating film 115 made of a high-k gate insulating film, an NMOS metal gate electrode 116 on the gate insulating film 115, and an n-type diffusion layer 113 and an n-type extension layer 114 formed in the p-type well region 103 on both sides of the metal gate electrode 116. Moreover, on the metal gate electrode 116, a polysilicon electrode 117 in which ions of an impurity such as phosphorus are implanted is formed. Offset spacers 100 made of a silicon nitride film are formed to cover sidewalls of the metal gate electrode 116 and the polysilicon electrode 117. Sidewalls 118 made of a silicon oxide film and a silicon nitride film are further formed on side surfaces of the offset spacers 100.

Moreover, upper portions of source/drain regions made of the n-type diffusion layer 113 and the n-type extension layer 114, and an upper portion of the polysilicon electrode 117 are silicided with nickel silicide (NiSi) or nickel platinum silicide (NiPtSi) (not shown). Moreover, a carbon-doped Si epitaxial layer containing 1%-3% of carbon (not shown) may be formed in the n-type source/drain regions.

Note that the gate insulating film 109 of the p-channel transistor 105 includes a high-k film made of an oxide film containing Hf, Si, and Zr, and the high-k film contains Al, Ta, and/or the like to adjust the work function. Moreover, the gate insulating film 115 of the n-channel transistor 106 includes a high-k film made of an oxide film containing Hf, Si, and Zr, and the high-k film contains La, Mg, and/or the like to adjust the work function.

Here, one of the characteristics of the semiconductor device 150 of the present embodiment is that the oxygen concentration at an interface between the offset spacers 100 and the metal gate electrodes 110, 116 is 1.0×10²⁰ atoms/cm³ or lower in volume atomic percentage which means a main component level, and is measured by SIMS. As described above, Document 1 describes the film formation temperature of an offset spacer silicon nitride film, and the amount of chlorine contained in a source gas. In contrast, in the present embodiment, attention is given to the amount of oxygen between the offset spacers 100 and the metal gate electrodes 110, 116. In particular, it is one of the characteristics that in the same furnace that is used to form the silicon nitride film, only an oxide film formed on the sidewalls of the metal gate electrode is selectively reduced, and is further renitrided, without reducing the high-k gate insulating film.

Here, the relationship between the oxygen concentration at the interface and the performance of the semiconductor device will be described below with reference to FIG. 2. FIG. 2 is a graph illustrating the gate leakage current with respect to the gate length. Usually, as described by the following expression 1 (Ohm's law), it is assumed that the gate leakage current (Ig) is proportional to the gate length (Lg) when the voltage (Vg) is constant.

Ig=Vg*Lg Expression 1

However, in the practice, as the gate length Lg decreases, deviations of the leakage current from Ohm's law begin to appear, and the leakage current shows a tendency to decrease to a value which is significantly smaller than that expected from Expression 1. This is probably because the sidewalls of the metal gate electrode are oxidized to serve as insulating films, and the proportion of such insulating films in the gate length increases as the gate length decreases.

Moreover, it is known that when the sidewalls of the metal gate electrode are oxidized, negative fixed charges are generated, so that the drivability decreases. This is a phenomenon called gate edge metamorphoses (GEM). In order to prevent the phenomenon to improve the drivability, it is probably effective to remove an oxide layer on the sidewalls of the metal gate electrode.

Note that the metal gate electrode here is made of a metal material used for a high-k gate insulating film/metal gate structure. Specifically, the metal gate electrode may be made of metal such as Al, Ti, Ta, W, Ru, and/or the like, or may be made of an alloy containing some of the above-listed metal elements. Alternatively, the metal gate electrode may be a nitride film or a carbonitride film of the above metal or the above alloy. Alternatively, the metal gate electrode may be made of a nitride film containing the above metal and silicon.

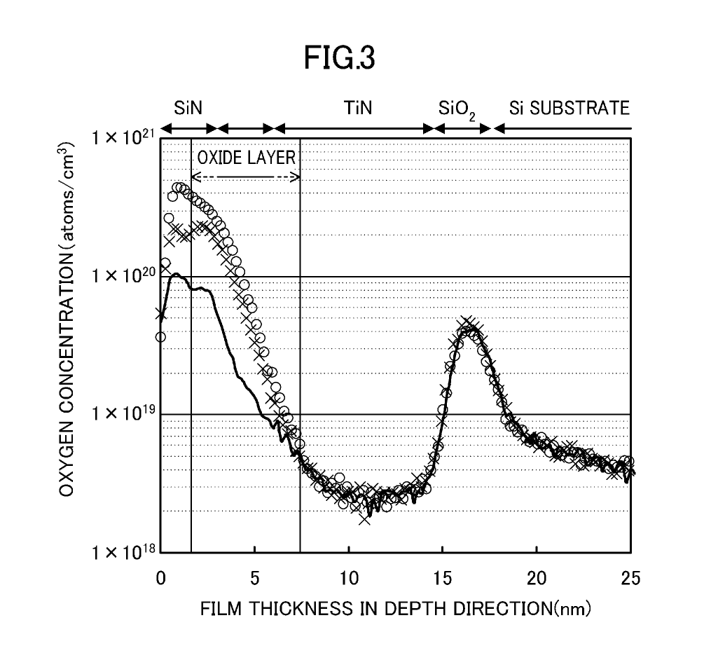

Next, the relationship between methods for fabricating a silicon oxide film on a metal gate electrode, and an oxide film formed on a surface of the metal gate electrode will be described with reference to FIG. 3. FIG. 3 shows results of measurement performed to estimate the amount of oxidation of gate electrode sidewalls, wherein the measurement is performed when a silicon nitride film is formed after a titanium nitride film having a thickness of 15 nm is formed on a silicon wafer on which no patterns are formed. Specifically, FIG. 3 shows results of secondary ion mass spectrometry (SIMS) in which the distribution of oxygen at an interface between the silicon nitride film and the titanium nitride film (corresponding to the metal gate electrode) is analyzed in the following three cases.

First, white open circles represent the result in the case where a resist is applied, then the resist is removed by plasma ashing, and thereafter the silicon nitride film is formed.

Moreover, cross marks represent the result in the case where an ashing oxide film and a natural oxide film formed on the titanium nitride film are removed by etching using hydrofluoric acid-based polymer cleaning liquid before forming the silicon nitride film, and then the silicon nitride film is formed.

Further, a solid line represents the result in the case where polymer cleaning similar to that described above and ammonia radical treatment in a furnace used to form the silicon nitride film are performed before forming the silicon nitride film, and then the silicon nitride film is formed. The ammonia radical treatment is a treatment in which ammonia radicals are added, for example, 40 cycles to reduce and renitride the oxide film on the titanium nitride film.

Here, the horizontal axis in FIG. 3 represents the thickness obtained by converting the sputtering rate, where the left end of the horizontal axis corresponds to the upper part of the SiN film, and the right end of the horizontal axis corresponds to the silicon substrate. Moreover, the vertical axis in FIG. 3 represents the number of oxygen atoms per unit volume (atoms/cm³).

Note that in the measurement method using SIMS, primary ionic species of Cs⁺ are used, and oxygen-18 is used to detect oxygen. The acceleration energy is 500 eV.

In the oxide layer of FIG. 3, oxygen profiles resulting from the ashing oxide film or the natural oxide film are shown between the silicon nitride film and the titanium nitride film, where the oxygen concentrations are different from each other.

In the case where the silicon nitride film is formed in an ashing oxidation state (represented by the white open circles in FIG. 3), oxygen diffuses from the oxide layer formed in the silicon nitride film and the titanium nitride film toward the silicon nitride film. Thus, the oxygen concentration of the silicon nitride film is about 4×10²⁰ atoms/cm³.

In contrast, in the case where only polymer cleaning is performed (represented by the cross marks in FIG. 3), the oxygen concentration of the silicon nitride film decreases down to about 2×10²⁰ atoms/cm³.

Moreover, in the case where the ammonia radical treatment is performed in addition to the polymer cleaning (represented by the solid line in FIG. 3), the oxygen concentration at the interface between the silicon nitride film and the titanium nitride film decreases, and the oxygen concentration of the silicon nitride film also decreases down to about 1×10²⁰ atoms/cm³.

As described above, when the silicon nitride film which will be offset spacers is formed after the ammonia radical treatment, the oxide film formed on the sidewalls of the metal gate electrode can be effectively removed. The metal gate electrode is covered with the silicon nitride film, and thus the sidewalls of the metal gate electrode is not reoxidized even when atmospheric exposure occurs in a subsequent process.

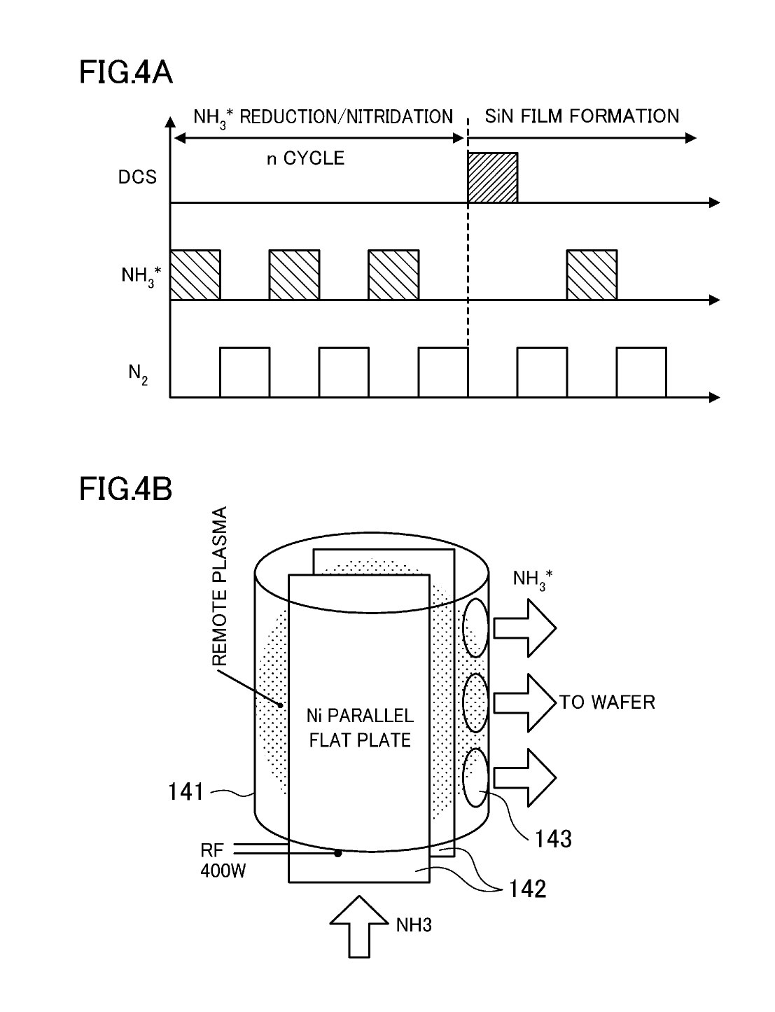

Next, the ammonia radical treatment allowing a reduction in the oxygen concentration at the interface between the metal gate electrode and the silicon oxide film and formation of the silicon nitride film will be described with reference FIGS. 4A-4B.

FIG. 4A schematically illustrates an ALD sequence in which selective reduction treatment by ammonia radicals is performed, before forming the silicon nitride film, in the same furnace that is used to form the silicon nitride film.

First, oxygen attached to the sidewalls of the metal gate electrode formed on the silicon wafer is removed by reduction, and the sidewalls are renitrided. For this purpose, ammonia radicals and an inert gas (nitrogen in this embodiment) are alternately supplied.

For the treatment by the ammonia radicals, the temperature in the furnace is preferably higher than or equal to 400° C. and lower than or equal to 800° C., and the pressure in the furnace is preferably 133 Pa (1 Torr) (the temperature in the furnace is more preferably higher than or equal to 400° C. and lower than or equal to 600° C.). The time period during which the ammonia radicals are supplied depends on the volume of the furnace. For example, when a vertical batch device having a volume of about 400 litters is used, a time period of about 1-100 seconds is required. In another case where a single-wafer-type device including a furnace having a small volume is used, reduction can be performed even with exposure for several milliseconds (msec).

A reducing gas is a hydrogen compound represented by the ammonia radicals. Hydrogen in the gas thermally reacts with the oxygen adhered to the metal gate electrode, so that oxygen atoms are eliminated as water. In order to evacuate the water resulting from the elimination, a purge is performed by using the inert gas. As the inert gas, a rare gas represented by Ar or N₂ is preferable. A substance supplied through a gas line is changed from ammonia to the inert gas so that the inside of the furnace and a gas injection section are preferably purged. For example, 2 slm (liter per minute in a normal state where the atmospheric pressure is 1 atm and the temperature is 0° C.) of N₂ gas is preferably supplied for about 1-10 seconds.

Exposure to the ammonia radicals and exposure to the inert gas as described above are repeated a predetermined number of times (three times in FIG. 4A, but the number of the exposures is not limited to that of the embodiment) to reduce the amount of oxygen at the sidewalls of the metal gate electrode to a preferred amount.

After this, a silicon source is introduced into the same furnace without exposing the silicon wafer to air, thereby forming the silicon nitride film. Dichlorosilane (DCS), monosilane, hexachlorosilane, and/or the like are/is suitable for the silicon source. In FIG. 4A, dichlorosilane is used, and 1 slm of the dichlorosilane is supplied with the pressure in the furnace being 665 Pa (5 Torr). After exposure to the dichlorosilane for 0.5 seconds, the purge by the inert gas is performed for 1 second, the ammonia radicals are supplied for 20 seconds, and the inert gas is supplied for 5 seconds. The above process is referred to as one cycle, and is repeated until a silicon nitride film having a preferred thickness is formed.

As described above, the silicon oxide film can be formed on the surface of the metal gate electrode, and the oxygen concentration at the interface between the silicon oxide film and the metal gate electrode can be reduced.

Next, a method for generating ammonia radicals is illustrated by an example in FIG. 4B. In a method illustrated in FIG. 4B, a pair of flat plate electrodes 142 made of nickel is arranged in a pipe 141 through which ammonia is supplied, and a high frequency (RF) is applied between the two flat plate electrodes 142. Here, for example, the flow rate of the ammonia is 2 slm, and a high-frequency voltage having an electric power of 400 W is applied to the flat plate electrodes 142 serving as discharge electrodes. In this way, radicals of the ammonia flowing between the flat plate electrodes 142 are formed, and are supplied through holes 143 to the silicon wafer, where each through hole 143 is formed in the pipe 141, and has a diameter of about 1 mm.

In another method, ammonia radicals may be generated by using a catalyst and ultraviolet light. When this method is used, a metal plate made of a platinum group element, an oxide of a Group 4 element, titanium dioxide, or the like as a metal catalyst is installed in an ammonia supply pipe. Moreover, to allow irradiation of the metal plate with the ultraviolet light, at least part of the ammonia supply pipe is made of glass, or the like so that light can be transmitted. In this configuration, while an ammonia gas is supplied to the ammonia supply pipe, the metal plate is irradiated with the ultraviolet light from the inside of the pipe or from the outside of the pipe, so that radicals of the ammonia can be formed through metal catalyst reaction.

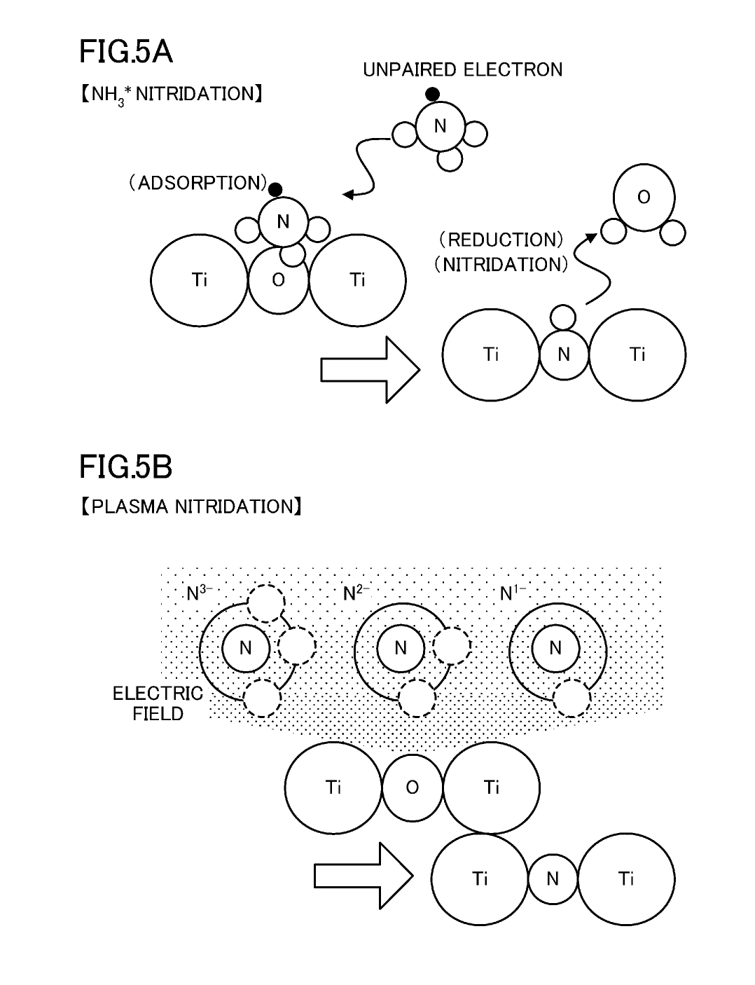

Next, FIG. 5A illustrates a reaction process when an ammonia radical is adsorbed on a titanium oxide film. Note that small circles without element symbols represent hydrogen. The titanium oxide film of the present embodiment is the natural oxide film or the ashing oxide film which is formed on the sidewalls of the metal gate electrode, and has a small thickness of about 1 nm, wherein bonding force between titanium and oxygen is not very strong. In particular, the bonding force between titanium and oxygen of the titanium oxide film of the present embodiment is weak compared to that of a crystalline titanium oxide film intentionally formed by CVD, or the like.

When a radical of ammonia is formed with the temperature in the furnace being kept at, for example, 550° C., an ammonia radical having an unpaired electron (NH₂. or NH₃.) is generated, and is adsorbed on a Ti—O surface. Here, oxygen of Ti—O formed by natural oxidation or the like and having a weak bonding force reacts with hydrogen of the ammonia radical, and is eliminated as water. Nitrogen of the ammonia from which hydrogen is eliminated by oxygen is bonded to a dangling bond of titanium, thereby forming the titanium nitride film.

Since the water resulting from the elimination may be re-adsorbed and/or reoxidized, the water is preferably evacuated. Thus, evacuation by an inert gas is performed.

Here, similar to the case of the metal gate electrode, sidewalls of the high-k gate insulating film formed under the metal gate electrode are exposed to ammonia radicals. In the exposure, in order to prevent reaction of the ammonia radicals with the high-k gate insulating film, it is preferable to prepare a state in which the high-k gate insulating film has higher energy than the ammonia radicals. That is, after forming the high-k gate insulating film, and before performing treatment with the ammonia radicals and forming the silicon oxide film, plasma nitridation and thermal treatment at a temperature of about 700° C.-1100° C. (e.g., 1000° C.) are preferably performed.

Note that the inventors also studied reduction and renitridation of the oxide layer of the sidewalls of the metal gate electrode by plasma nitridation. However, as described below, the inventors found that the treatment using ammonia radicals is preferable.

In the plasma nitridation, as illustrated in FIG. 5B, nitrogen is brought into an ionic state (N⁻, N²⁻, N³⁻), an electric field is applied so that the nitrogen physically collides with the wafer, and then the nitrogen is bonded to a target by thermal treatment, or the like. This may damage the high-k gate insulating film. Moreover, the silicon substrate may be nitrided, and Si of source/drain regions may be etched by cleaning, or the like in a subsequent process. Thus, using the plasma nitridation leads to degradation of transistor characteristics. Therefore, the treatment by the ammonia radicals is preferable.

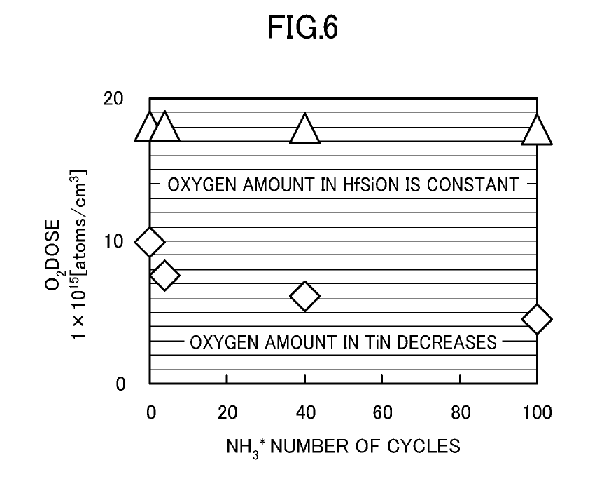

Next, FIG. 6 illustrates result of measurement of the oxygen concentration of films after the treatment by the ammonia radicals, where the oxygen concentration is measured by electron probe micro analysis (EPMA). An example case is illustrated where an ALD-TiN film (TiN film formed by an ALD method) and a HfSiON film are formed on a silicon wafer, and then are exposed to ammonia radicals 4, 40, or 100 cycles to form a silicon nitride film having a thickness of 2 nm.

As illustrated in FIG. 6, the oxygen concentration of the HfSiON film (represented by white open triangles) does not significantly change even when the cycle of the treatment is repeated. In contrast, as the number of cycles of the ammonia radical treatment increases, the oxygen concentration of the TiN film (indicated by white open squares) decreases. Specifically, when the ammonia radical treatment is not performed, the oxygen concentration is about 1×10¹⁶ atoms/cm², whereas when the ammonia radical treatment is performed 100 cycles, the oxygen concentration decreases down to about 4.5×10¹⁵ atoms/cm².

Thus, it is possible to reduce only the amount of oxygen on TiN without reducing the amount of oxygen in HfSiON. That is, only the metal gate electrode can be selectively reduced without reducing the gate insulating film.

Note that in order to reduce the amount of oxygen with a small number of cycles, reaction with the titanium oxide film may be promoted by increasing the flow rate of the ammonia, or increasing the power of the high frequency. Moreover, in order to efficiently evacuate the generated water, increasing the flow rate of the inert gas, or increasing the time period of evacuation may be effective.

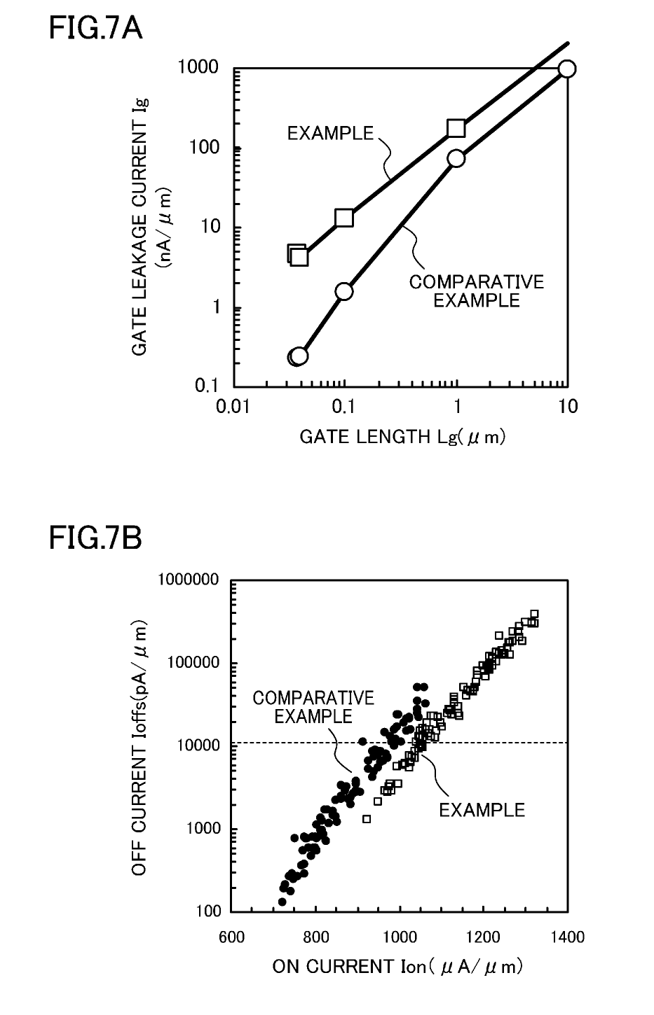

Next, the relationship between the gate length and the gate leakage current of an example of the present embodiment and a comparative example is illustrated in FIG. 7A. In the example, the ammonia radical treatment is performed 40 cycles on a metal gate electrode, and then a silicon nitride film is formed in-situ in a manner similar to that described above. In contrast, in the comparative example, only formation of a silicon nitride film on the metal gate electrode is performed.

In the comparative example, when the gate length is 1 μm or shorter, the leakage current deviates from Ohm's law. In contrast, in the example, it is found that linearity is retained down to a gate length of about 30 nm, and the influence of a titanium oxide film on sidewalls of the metal gate electrode is reduced.

Moreover, FIG. 7B is a view illustrating drive currents of semiconductor devices of the example and the comparative example with the on current of a transistor on the horizontal axis and the off current on the vertical axis. As illustrated in FIG. 7B, the on current of the example increases compared to that of the comparative example. For example, when the off current is 10 nA/μm (10000 pA/μm), the on current of the example is higher than that of the comparative example by about 11%.

Note that in order to perform SIMS analysis illustrated in FIG. 3, a spot of about 1×1 mm at minimum is required to improve the secondary ion strength. However, since the gate length is 50 nm or smaller, and the thickness of the metal gate electrode is about 5 nm-20 nm, it is difficult to evaluate the sidewalls of the metal gate electrode of the transistor by the SIMS analysis.

On the other hand, it has become possible in recent years to easily observe a segregated element in a transistor structure by three dimensional atom probe spectrometry. The three dimensional atom probe spectrometry is a spectrometry in which atoms at a tip of a probe processed into a needle shape by a focus ion beam (FIB) or the like are ionized by a laser, and are detected by a time of flight (TOF)-type detector to visualize three-dimensional distribution of the atoms.

With the three-dimensional atom probe spectrometry, three-dimensional mapping at the atomic level is possible, and the depth resolution and the spatial resolution are both about several angstroms (tens of nanometers) in theory. Thus, a very small portion such as the sidewalls of the metal gate electrode can be analyzed.

Moreover, oxygen of the sidewalls of the metal gate electrode can also be observed by TEM utilizing electron energy loss spectroscopy (EELS). With this method, portions containing oxygen appear bright. In the comparative example, it can be seen that TiN contained in the metal gate electrode is oxidized, and sidewalls of a polysilicon electrode are also oxidized, thereby forming a silicon oxide film. In contrast, in the example of the present embodiment, it can be observed that oxygen of the sidewalls of the metal gate electrode and sidewalls of a polysilicon electrode has been removed.

As described above, the inventors of the present application closely examined physical properties of the oxide film on the sidewalls of the metal gate electrode, and proposed and realized selective reduction and renitridation by ammonia radicals. Thus, the drivability of the transistor is improved (drivability of the transistor is less susceptible to GEM degradation).

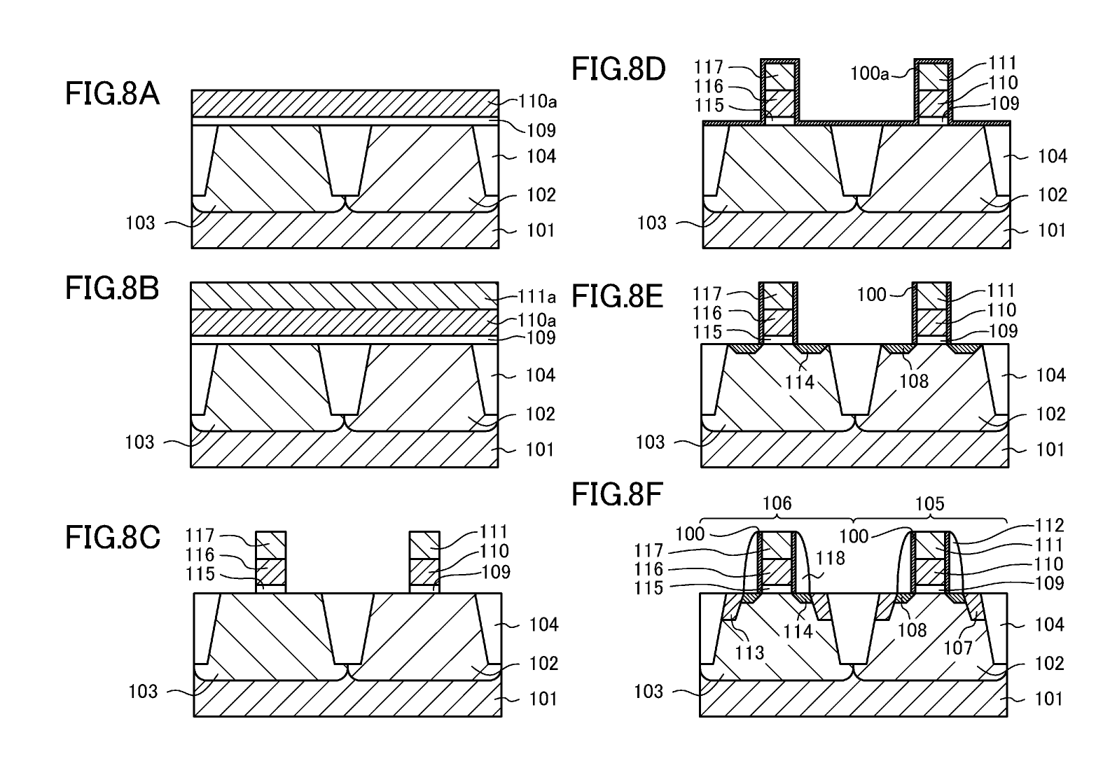

Next, a method for fabricating the semiconductor device 150 of FIG. 1 will be described with reference to FIG. 8A-8F which are cross-sectional views schematically illustrating processes of the fabrication.

First, as illustrated in FIG. 8A, an n-type well region 102 and a p-type well region 103 are formed on a silicon substrate 101. The n-type well region 102 and the p-type well region 103 are dielectrically isolated from each other by a device isolation layer 104 made of a silicon oxide film formed as STI. Moreover, over the n-type well region 102 and the p-type well region 103, a gate insulating film 109 and a metal containing film 110a which will be processed into a metal gate electrode 110 are sequentially stacked.

Here, the gate insulating film 109 is formed as, for example, a high-k gate insulating film formed by stacking a film made of a high-k material on a silicon oxide film having a thickness of about 1.0 nm obtained by oxidizing the silicon substrate 101 in a water vapor atmosphere, a nitrogen monoxide atmosphere, or the like. The high-k material may be, for example, an oxide containing a Group 4 element such as Hf or Zr as a main component. Alternatively, the high-k material may be an oxide called silicate which is made of Hf, Zr, or the like and Si. Alternatively, the high-k material may be an oxide called aluminates which is made of Hf, Zr, or the like and Al. Alternatively, the high-k material may be oxynitride obtained by adding nitrogen to the material listed above by plasma nitridation, ammonia nitridation, or the like.

To form the high-k gate insulating film, metal organic chemical vapor deposition (MOCVD), atomic layer deposition (ALD), physical vapor deposition (PVD), or the like may be used. Moreover, when nitridation treatment is performed, thermal treatment at 1000° C. or higher is preferably performed to prevent outward diffusion of nitrogen caused by thermal treatment in a subsequent process.

In order to control the threshold voltage, different high-k materials are preferably added to an n-channel high-k gate insulating film and a p-channel high-k gate insulating film. For example, LaO, MgO, and/or the like are/is preferably added to the n-channel high-k gate insulating film, and AlO, TaO, and/or the like are/is preferably added to the p-channel high-k gate insulating film.

The metal containing film 110a includes, as a material, an alloy containing a metallic element(s) such as Ti, W, Ta, Ru, and/or Al as a main component, a nitride of the alloy, or a nitride of the alloy further containing Si, and is formed by MOCVD, ALD, PVD, or the like.

Next, the process of FIG. 8B is performed. First, a surface of the metal containing film 110a is cleaned with a hydrogen peroxide solution. The cleaning is performed to remove a natural oxide film formed on the metal containing film 110a, and a metal layer altered by application and removal of a resist to form a region in which the metal gate electrode 110 is not arranged on gate insulating film 109. After that, on the metal containing film 110a, a polysilicon film 111a which will be processed into a polysilicon electrode 111 is formed to have a thickness of 100 nm. Since interface resistance increases when an oxide layer exists at an interface between the metal containing film 110a and the polysilicon film 111a, it is preferable to perform the cleaning with the hydrogen peroxide solution.

In order to obtain the polysilicon film 111a, an amorphous silicon film may be formed by using silane (SiH₄) and/or disilane (Si₂H₆) within a temperature range from 500° C. to 550° C. both inclusive, and then performing thermal treatment to make the amorphous silicon film polysilicon. Alternatively, polysilicon may be formed within a temperature range from 600° C. to 630° C. both inclusive. Alternatively, an electrode made of silicon germanium instead of polysilicon may be formed. For this purpose, for example, germane (GeH₄) in addition to silane is used as a material.

Next, the process of FIG. 8C is performed. First, a gate electrode resist pattern (not shown) is formed by photolithography and etching. Subsequently, the polysilicon film 111a and the metal containing film 110a are anisotropically etched with a halogen-based etching gas to form gate electrodes. That is, the metal gate electrode 110 and the polysilicon electrode 111 on the metal gate electrode 110 are formed on the n-type well region 102, and a metal gate electrode 116 and a polysilicon electrode 117 on the metal gate electrode 116 are formed on the p-type well region 103. Here, in order to prevent excessive etching of the silicon substrate 101, etching selectivity is ensured for each of the gate insulating film 109 serving as the high-k gate insulating film and the silicon substrate 101 so that etching stops at the gate insulating film 109. Note that when the gate insulating film 109 is subjected to thermal treatment at 1000° C. or higher after nitridation, the etching selectivity can be easily ensured.

Next, the resist is removed by ashing in oxygen plasma. Then, polymer remaining after the etching the metal gate electrode 110 and the gate insulating film 109 remaining in unnecessary portions other than the portion under the metal gate electrode 110 are removed by a fluorine-based cleaning agent. Here, the oxide layer on sidewalls of the metal gate electrode 110 is more or less etched. Thus, attention has to be paid so that the sidewalls of the metal gate electrode 110 do not become narrow in the middle due to excessive etching.

Subsequently, as illustrated in FIG. 8D, a silicon nitride film 100a which will be processed into offset spacers 100 is formed. Since the silicon nitride film 100a is necessarily exposed to air, a natural oxide film is necessarily formed on the sidewalls of the metal gate electrode 110. The natural oxide film causes GEM, which causes a reduction in drivability.

Thus, before forming the silicon nitride film 100a, the natural oxide film on a surface of the metal gate electrode 110 is reduced and renitrided by ammonia radicals. Specifically, the wafer is inserted in a furnace used for film formation, a vacuum is created in the furnace, and then the wafer is alternately exposed to the ammonia radicals and an inert gas. In this way, a remaining film of an ashing oxide film and the natural oxide film adhered to the surface of the metal gate electrode 110 are removed. Then, in order to prevent reoxidation due to atmospheric exposure, in the same furnace, the silicon nitride film 100a is formed in-situ to have a thickness of about 5 nm-10 nm. Further details of the process are as those described with reference to FIGS. 4A and 4B.

Next, the process of FIG. 8E is performed. First, the silicon nitride film 100a is anisotropically dry etched with a halogen-based gas so that the silicon nitride film 100a remains on gate electrode sidewalls as the offset spacers 100, and the silicon nitride film 100a on other portions is removed.

Subsequently, the n-type well region 102 is protected by a resist (not shown), and ions of phosphorus, arsenic, antimony, and/or the like serving as an n-type impurity are implanted into the p-type well region 103. After this, the resist on the n-type well region 102 is removed. Subsequently, the p-type well region 103 is protected by a resist (not shown), and ions of boron, indium, and/or the like serving as a p-type impurity are implanted into the n-type well region 102. Thereafter, the resist on the p-type well region 103 is removed, and ionic species are activated by thermal treatment at, for example, 1000° C. or higher. In this way, a p-type extension layer 108 and an n-type extension layer 114 are formed.

Next, the process of FIG. 8F is performed. Here, a silicon oxide film is formed to have a thickness of 5 nm-10 nm, a silicon nitride film is successively formed to have a thickness of 10 nm-30 nm, and anisotropic dry etching is performed. In this way, sidewalls 112 and 118 are formed on sidewalls of the gate electrodes (the metal gate electrode 110 and the polysilicon electrode 111, and the metal gate electrode 116 and the polysilicon electrode 117) via the offset spacers 100. Although the sidewalls here include two layers, the silicon nitride film and the silicon nitride film, the sidewalls may be made of one silicon nitride film, or may be made of one silicon oxide film.

Subsequently, the n-type well region 102 is protected by a resist (not shown), and ions of phosphorus, arsenic, antimony, and/or the like serving as an n-type impurity are implanted into the p-type well region 103 to form an n-type diffusion layer 113. Thereafter, the resist on the n-type well region 102 is removed. Subsequently, the p-type well region 103 is protected by a resist (not shown), and ions of boron, indium, and/or the like serving as a p-type impurity are implanted into the n-type well region 102 to form a p-type diffusion layer 107. Thereafter, thermal treatment at, for example, 900° C.-1050° C. is performed to activate ionic species of the n-type diffusion layer 113 and the p-type diffusion layer 107, thereby forming source/drain regions.

Then, upper portions of the source/drain regions and upper portions of the polysilicon electrodes 111 and 117 are silicided with Ni or Pt. Moreover, a silicon nitride film (not shown) which will be a contact hole etching stopper and a silicon oxide film which will be an interlayer dielectric film (not shown) are formed, and general processes such as a planarization process are performed to form the semiconductor device 150.

With the semiconductor device described above and the method for fabricating the same, the oxygen concentration of the sidewalls of the metal gate electrode is reduced, so that it is possible to improve the drivability of the semiconductor device. The semiconductor device described above and the method for fabricating the same are useful to various electronic devices using semiconductor integrated circuits.

What is claimed is:

1. A method for fabricating a semiconductor device, the method comprising:
forming a metal containing film on a substrate;
exposing the metal containing film to an ammonia radical in a reaction chamber;
evacuating gas generated in the exposing by supplying an inert gas into the reaction chamber; and
after repeating the exposing and the evacuating a predetermined number of times, forming a silicon nitride film covering the metal containing film in the reaction chamber without atmospheric exposure.

2. The method of claim 1, wherein
the exposing and the evacuating are repeated until a natural oxide film formed on a surface of the metal containing film is reduced.

3. The method of claim 1, wherein
the exposing is performed within a temperature range from 400° C. to 800° C. both inclusive.

4. The method of claim 1, wherein
the ammonia radical is generated by supplying ammonia between a pair of electrode plates to which a high-frequency voltage is applied.

5. The method of claim 1, wherein
the ammonia radical is generated by supplying ammonia to a metal catalyst and irradiating the metal catalyst with an ultraviolet ray.

6. The method of claim 5, wherein
the metal catalyst includes a platinum group element, Ti, Zr, or Mn.

7. The method of claim 1, wherein
the metal containing film is a metal gate electrode formed on the substrate via a high-dielectric-constant gate insulating film, and
the high-dielectric-constant gate insulating film includes at least one of an oxide of a Group 4 element, an oxide of a Group 4 element and Si, or an oxide of a Group 4 element and Al.

8. The method of claim 7, wherein
the Group 4 element is at least one of Hf or Zr.

9. The method of claim 1, wherein
the metal containing film is a metal gate electrode formed on the substrate via a high-dielectric-constant gate insulating film, and
the metal gate electrode is made of an alloy containing a metallic element as a main component, a nitride of an alloy containing a metallic element as a main component, or a nitride of an alloy containing a metallic element as a main component and containing Si.

10. The method of claim 9, wherein
the metallic element is at least one of Ti, W, Ta, Ru, or Al.

11. The method of claim 1, wherein
the metal containing film is a metal gate electrode formed on the substrate via a high-dielectric-constant gate insulating film,
a p-channel transistor including the high-dielectric-constant gate insulating film and the metal gate electrode is formed, and
the high-dielectric-constant gate insulating film contains at least one of AlO or TaO.

12. The method of claim 1, wherein
the metal containing film is a metal gate electrode formed on the substrate via a high-dielectric-constant gate insulating film,
an n-channel transistor including the high-dielectric-constant gate insulating film and the metal gate electrode is formed, and
the high-dielectric-constant gate insulating film contains at least one of LaO or MgO.

13. The method of claim 1, wherein
the metal containing film is a metal gate electrode formed on the substrate via a high-dielectric-constant gate insulating film, and
in the forming the metal containing film, thermal treatment within a temperature range from 700° C. to 1100° C. both inclusive is performed on the high-dielectric-constant gate insulating film before forming the metal gate electrode.

14. The method of claim 1, wherein
the metal containing film is a metal gate electrode formed on the substrate via a high-dielectric-constant gate insulating film, and
the silicon nitride film is formed by ALD, and is processed into offset spacers.

15. A semiconductor device comprising:
a transistor structure including a metal gate electrode formed on a substrate via a high-dielectric-constant gate insulating film; and
offset spacers made of a silicon nitride film formed on sidewalls of the metal gate electrode, wherein
a concentration of segregated oxygen between the metal gate electrode and each offset spacer is equal to or lower than 1×10²⁰ atoms/cm³.
